(19) United States
(12) Patent Application Publication
(10) Pub. No.: US 2009/0166008 A1
(43) Pub. Date: Jul. 2, 2009

(54) HEAT SPREADER WITH VAPOR CHAMBER

(75) Inventors: CHENG-TIEN LAI, Tu-Cheng (TW); ZHI-YONG ZHOU, Shenzhen (CN); QIAO-LI DING, Shenzhen (CN)

Correspondence Address: PCE INDUSTRY, INC.;ATT. Steven Reiss, 458 E. LAMBERT ROAD, FULLERTON, CA, 92835, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 11/964,913

(22) Filed: Dec. 27, 2007

(51) Int. Cl. F28D 15/04; H01L 23/427

(52) U.S. Cl. 165/104.33; 165/185; 361/704

(57) ABSTRACT

A heat spreader for cooling an electronic component includes a lower plate, an upper plate fixed on the lower plate, a working liquid contained between the lower plate and the upper plate, and a wick structure formed between the lower plate and the upper plate. Each of the upper plate and the lower plate defines a cavity receiving a portion of the wick structure therein, and a plurality of grooves extending radially from the cavity to a periphery thereof.

### BACKGROUND OF THE INVENTION

1. Field of the Invention

The present invention relates to a heat spreader, and more particularly to a heat spreader with an improved vapor chamber for preventing liquid contained therein from drying out.

2. Description of Related Art

It is well known that heat is generated during operations of electronic components, such as integrated circuit chips. To ensure normal and safe operations, cooling devices such as heat sinks are often employed to dissipate the generated the heat away from these electronic components.

As progress continues to be made in the electronics art, more components on the same real estate generate more heat. The heat sinks used to cool these chips are accordingly made larger in order to possess a higher heat removal capacity, which causes the heat sinks to have a much larger footprint than the chips. Generally speaking, a heat sink is more effective when there is a uniform heat flux applied over an entire base of the heat sink. When a heat sink with a large base is attached to an integrated circuit chip with a much smaller contact area, there is significant resistance to the heat flow to the other portions of the heat sink base which are outside reach of the chip.

A mechanism for overcoming the resistance to heat flow in a heat sink base is to attach a heat spreader to the heat sink base or directly make the heat sink base as a heat spreader. Conventionally, the heat spreader includes a vacuum chamber defined therein, a meshed layer or sintered layer acting as a wick structure provided in the chamber and lining an inside wall of the chamber, and a working fluid contained in chamber. As the integrated circuit chip is maintained in thermal contact with the heat spreader, the working fluid contained in the wick structure corresponding to a hot contacting location vaporizes. The vapor then spreads to fill the chamber, and wherever the vapor rushes into contact with a cooler surface of the chamber, it releases its latent heat of vaporization and condenses. The condensate reflows to the hot contacting location via a capillary force generated by the wick structure. Thereafter, the condensate frequently vaporizes and condenses to form a circulation to thereby remove the heat generated by the chip.

However, in the conventional heat spreader, since a reflowing direction of the condensate back toward the hot contacting location is opposite to a spreading direction of the vapor toward the other cooler locations, a shearing force occurs at an interface between the condensate and the vapor, which obstructs the condensate and render it remote from the hot contacting location. When a quantity of the heat generated by the chip reaches a critical number, a spreading speed of the vapor would be so rapid that the shearing force becomes large enough to bring all of the condensate away the hot contacting location. Therefore, no condensate back to the hot contacting location causes the condensate at this location dries out, and the heat spreader fails to work.

What is needed, therefore, is a heat dissipating device which can overcome the above-mentioned disadvantages.

### SUMMARY OF THE INVENTION

A heat spreader for cooling an electronic component comprises a lower plate, an upper plate fixed on the lower plate to cooperatively define a chamber, working liquid contained in the chamber, and a wick structure formed between the lower plate and the upper plate. Each of the upper plate and the lower plate defines a cavity receiving a portion of the wick structure therein, and a plurality of grooves extending radially from the cavity to a periphery thereof. The liquid can be transferred from cooler portions of the heat spreader to the cavity through the grooves, which provide different pathways from the chamber in which the vapor spreads. Therefore, a distribution of the vapor flux acting to the liquid flow can be reduced, and a dry-out problem of the heat spreader is resolved.

Other advantages and novel features of the present invention will become more apparent from the following detailed description when taken in conjunction with the accompanying drawings, in which:

### BRIEF DESCRIPTION OF THE DRAWINGS

Many aspects of the present apparatus can be better understood with reference to the following drawings. The components in the drawings are not necessarily drawn to scale, the emphasis instead being placed upon clearly illustrating the principles of the present apparatus. Moreover, in the drawings, like reference numerals designate corresponding parts throughout the several views.

FIG. 1 is an assembled, isometric view of a heat spreader in accordance with a preferred embodiment of the present invention;

FIG. 2 is an exploded view of FIG. 1;

FIG. 3 is an inverted view of a top plate of the heat spreader of FIG. 2;

FIG. 4 is an assembled view of a wick structure and a lower plate of the heat spreader of FIG. 2; and

FIG. 5 is a cross-sectional view of FIG. 4 taking along a line V-V.

### DETAILED DESCRIPTION OF THE INVENTION

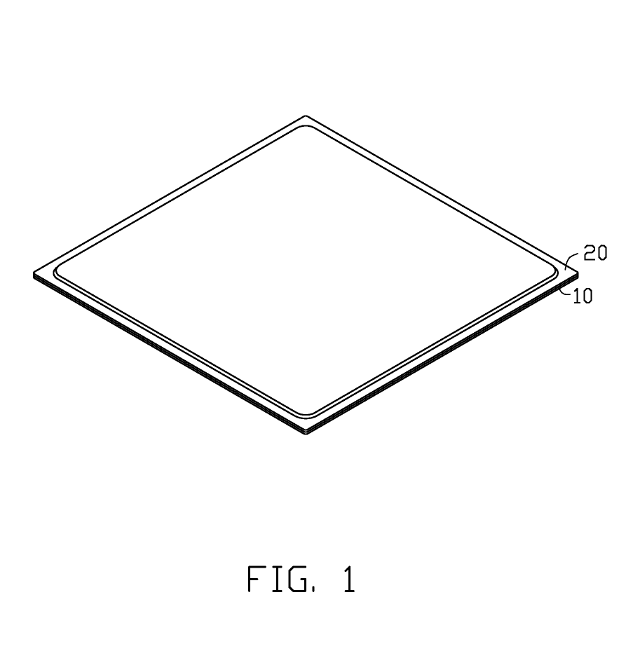

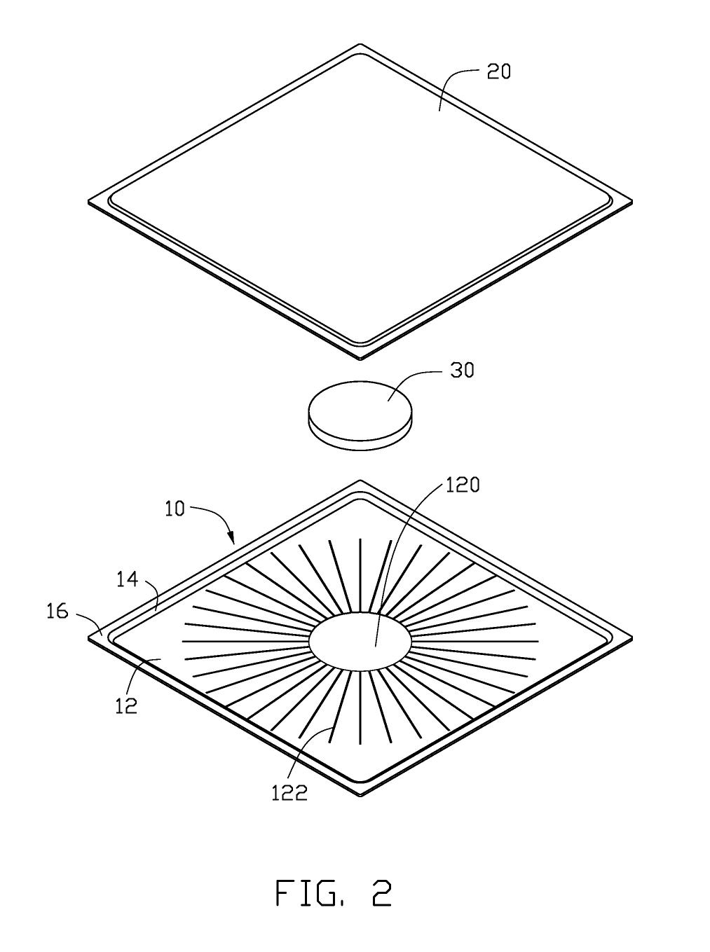

Referring to FIGS. 1-2, a heat spreader in accordance with a preferred embodiment of the present invention is used for an electronic component (not shown) to dissipate heat therefrom. The heat spreader comprises a lower plate 10, an upper plate 20 hermetically fixed on the lower plate 10, a wick structure 30 formed between the lower plate 10 and the upper plate 20, and a kind of working liquid (not shown) acting as a coolant contained between the lower plate 10 and the upper plate 20.

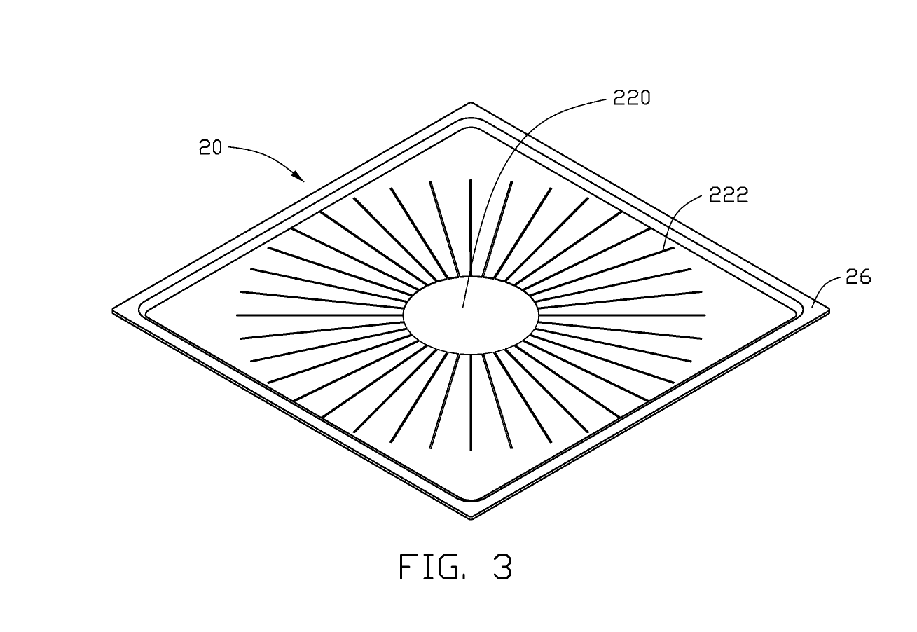

Also shown in FIG. 3, since the lower plate 10 and the upper plate 20 have same configurations, only one thereof would be described as given below for conciseness. The lower plate 10 comprises a square tank (not labeled) and a flange 16 extending outwardly and horizontally from a top of the tank. The tank comprises a square board 12 and a sidewall 14 extending upwardly and perpendicularly from a periphery of the board 12. The board 12 defines a circular cavity 120 in a central area thereof and a plurality of elongated grooves 122 extending radially and outwardly from and communicating with the cavity 120. A part of a bottom of the board 12 located corresponding to the cavity 120 is for contacting the electronic component to absorb the heat therefrom. The grooves 122 cooperatively form a circular shape with corresponding extremities thereof reaching the periphery of the board 12, to thereby transfer the working liquid from other portions of the board 12 to the cavity 120. The upper plate 20 is secured on the lower plate 10 by air-tightly and liquid-tightly engaging the flange 26 thereof with the flange 16 of the lower plate 10, thereby defining a chamber (not labeled) between the upper plate 20 and the lower plate 10 for filling the working liquid therein.

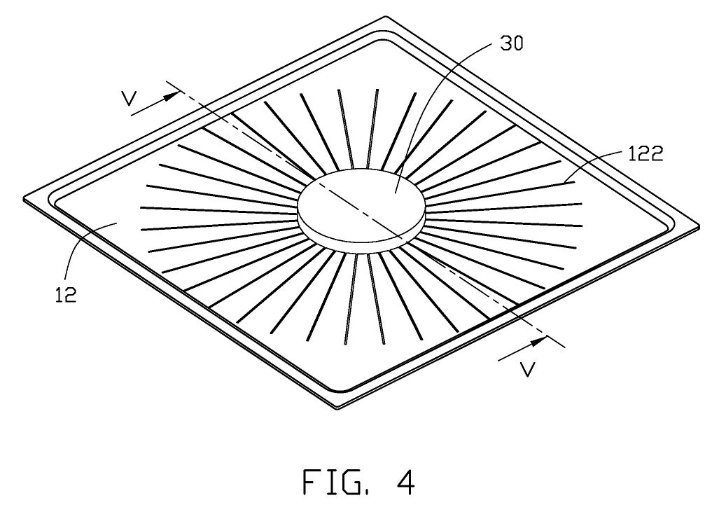

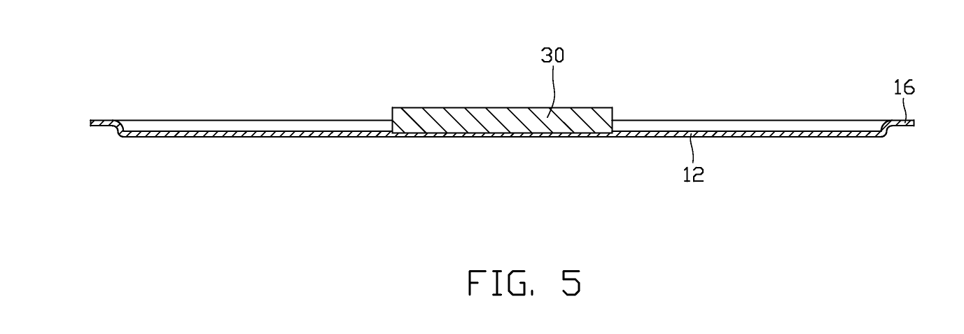

Referring also FIGS. 4-5, the wick structure 30 is sandwiched between the lower plate 10 and the upper plate 20. The wick structure 30 is made by sintering metal power in the preferred embodiment of the present invention; alternatively, the wick structure 30 also can be other types that are well known by a skilled person in the related art. The wick structure 30 has a cylindrical configuration with its top portion fitting into the cavity 220 of the upper plate 20 and its bottom portion retained into the cavity 120 of the lower plate 10. For generating capillary force, the wick structure 30 forms a large amount of pores (not shown) therein, which are in liquid communication with the grooves 122, 222 of the lower plate 10 and the upper plate 20, thus allowing the working liquid therethrough.

In use, the heat spreader is disposed on the electronic component with the part corresponding to the cavity 120 of the lower plate 12 contacting the electronic component. As the electronic component operates and generates heat, the working liquid is heated and vapored to vapor. The vapor spreads to fill the chamber between the lower plate 10 and the upper plate 20 along a radial outward direction. As the vapor reaches other cooler portions of the heat spreader outside reach of the electronic component, it exchanges heat with the other portions of the heat spreader and is condensed to liquid, whereby the heat is dissipated by the other portions of the heat spreader to an ambient. The liquid on the other portions of the lower plate 10 which are not in direct contact with the electronic component refluences to the cavity 120 through the grooves 122 of the lower plate along a radial inward direction, via capillary force generated by the grooves 122; the liquid on a bottom of the upper plate 20 refluences to the wick structure 30 through the grooves 222 along the radial inward direction, and then reflows to the cavity 120 of the lower plate 10 via the wick structure 30. The liquid is vapored and condensed continuously, thereby circling the heat exchange between the electronic component and the ambient.

Since there are grooves 122, 222 formed in the upper plate 20 and the lower plate 10, the liquid reflowing in the grooves has a large area contacting inner faces of the grooves 122, 222, and only has a small area exposed within the vapor; that is to say, the reflowing liquid only has a small area influenced by the vapor, whereby a shearing force occurring at the interface between the vapor and the liquid can be controlled to be small. Even if a spreading speed of the vapor is high, the small shearing force can not tack all of the liquid away the cavity 120, 220; therefore, the liquid located near the cavity 120, 220 of the heat spreader is prevented from drying out.

It is believed that the present invention and its advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat spreader adapted for dissipating heat from an electronic component, comprising:
a lower plate defining a plurality of grooves therein;
an upper plate fixed on the lower plate;
a working liquid contained between the upper plate and the lower plate; and
a wick structure sandwiched between the lower plate and the upper plate, having a plurality of pores defined therein,
wherein the plurality of grooves communicates with the pores of the wick structure.

2. The heat spreader as claimed in claim 1, wherein the wick structure is formed at a central area of the lower plate.

3. The heat spreader as claimed in claim 1, wherein the lower plate comprises a board, a sidewall extending upwardly from a periphery of the board, and a flange extending outwardly from a top of the sidewall, the plurality of grooves being defined at a top face of the board.

4. The heat spreader as claimed in claim 3, wherein the board defines a cavity at a central area of the top face thereof, the plurality of grooves communicating with the cavity.

5. The heat spreader as claimed in claim 4, wherein a bottom portion of the wick structure is received in the cavity.

6. The heat spreader as claimed in claim 4, wherein the plurality of grooves extends radially and outwardly from the cavity of the lower plate.

7. The heat spreader as claimed in claim 1, wherein the upper plate defines a cavity in a central portion thereof, a top portion of the wick structure being received in the cavity of the upper plate.

8. The heat spreader as claimed in claim 7, wherein the upper plate further defines a plurality of grooves extending radially and outwardly from and communicating with the cavity.

9. The heat spreader as claimed in claim 1, wherein the lower plate has a configuration identical to that of the upper plate.

10. The heat spreader as claimed in claim 1, wherein the wick structure has a cylindrical shape.

11. The heat spreader as claimed in claim 1, wherein the wick structure is formed by sintering metal power.

12. A heat spreader comprising:
a lower plate comprising a tank and a flange extending outwardly from a top of the tank;
an upper plate comprising another tank and another flange extending outwardly from a bottom of the another tank and engaging with the flange of the lower plate;
a kind of working liquid contained between the tank and the another tank; and
a wick structure sandwiched between and contacting the tank and the another tank, wherein the tank therein defines a plurality of grooves extending from a location corresponding to the wick structure to locations adjacent to a periphery thereof.

13. The heat spreader as claimed in claim 12, wherein the tank defines a cavity receiving a bottom of the wick structure therein, the plurality of grooves communicating with the cavity.

14. The heat spreader as claimed in claim 13, wherein the plurality of grooves extends from the cavity in a radial and outward manner.

15. The heat spreader as claimed in claim 12, wherein the wick structure is located at a central area of the tank and has a cylindrical configuration.

16. The heat spreader as claimed in claim 12, wherein the wick structure is made by sintering metal power.

17. A heat spreader comprising:
a lower plate;
an upper plate fixed on the lower plate to cooperatively define a sealed chamber therebetween;
a coolant contained in the chamber; and
a wick block received in the chamber and contacting the lower plate and the upper plate, wherein at least one of the lower plate and the upper plate defines a cavity and a plurality of grooves extending from the cavity and communicating with the chamber, the wick block is partially received in the cavity.

18. The heat spreader as claimed in claim 17, wherein the cavity is circular and defined at a central area of the at least one of the upper plate and the lower plate.

19. The heat spreader as claimed in claim 17, wherein the plurality of grooves extends to a periphery of the at least one of the lower plate and the upper plate.

20. The heat spreader as claimed in claim 17, wherein the plurality of grooves equidistantly surrounds the cavity.
